(19) United States
(12) Patent Application Publication
(10) Pub. No.: US 2021/0239738 A1
(43) Pub. Date: Aug. 5, 2021

(54) SENSORS WITH IMPEDANCE ELEMENTS ON SUBSTRATE FOR HIGH VOLTAGE SEPARABLE CONNECTORS

(71) Applicant: 3M INNOVATIVE PROPERTIES COMPANY, St. Paul, MN (US)

(72) Inventors: Jaylon D. Loyd, Austin, TX (US); Christopher R. Wilson, Austin, TX (US); Carl J. Wentzel, Austin, TX (US); Richard D. Twigg, Leander, TX (US); Harald Westkamp, Hattingen (DE); Mark Gravermann, Erkelenz (DE); Gunther A. J. Stollwerck, Krefeld (DE); Jens Weichold, Erkelenz (DE)

(21) Appl. No.: 16/972,163

(22) PCT Filed: Jun. 13, 2019
(86) PCT No.: PCT/IB2019/054969

§ 371 Date: Dec. 4, 2020

Related U.S. Application Data
(60) Provisional application No. 62/688,768, filed on Jun. 22, 2018.

(51) Int. Cl. G01R 15/14; G01R 1/04; H05K 1/03; H05K 1/16

(52) U.S. Cl. CPC G01R 15/144; G01R 1/0416; H05K 2201/10151; H05K 1/16; H05K 1/0393

(57) ABSTRACT

A sensor for a separable connector includes an elongate plug body extending along an axis and includes an insulating resin. The plug body includes a high voltage connection at least partially encased by the insulating resin and includes a low voltage connection spaced along the axis from the high voltage connection. The plug body also includes a substrate at least partially encased in the insulating resin and extending around the axis between a high voltage portion and a low voltage portion of the substrate. A circuit is disposed on the substrate and extends from the high voltage portion to the low voltage portion of the substrate. The circuit includes a plurality of first impedance elements electrically coupled between the high and low voltage connections. One or more second impedance elements are electrically coupled to the circuit via the low voltage connection to form a voltage divider.

### TECHNICAL FIELD

This disclosure relates to sensors for high voltage and, in particular, relates to sensors for high voltage separable connectors, each having an elongate plug body extending along an axis and impedance elements disposed on a substrate, which extends around the axis, between a high voltage connection and a low voltage connection.

### BACKGROUND

As electrical power distribution becomes more complex through the advent of renewable energy, distributed generation, and the adoption of electric vehicles, intelligent electrical distribution and associated electrical sensing is becoming more useful and even necessary. Useful sensing may include voltage, current, and the time relationship between voltage and current at various locations within a power distribution network.

Many existing relatively high voltage transformers and switchgears have a dedicated space for cable accessories, particularly in higher voltage applications (for example, 5 kV to 69 kV, or higher). Many of these transformers and switchgear are of a variety referred to in the power utility industry as dead-front. Dead-front means there are no exposed relatively high voltage surfaces in the connection between a power cable and the transformer or switchgear. Such cable accessory connections are sometimes referred to as elbows, T-bodies, or separable connectors.

Many cable accessories implement testpoints to provide a scaled fraction of the line voltage residing on the shielded and insulated conductor of the cable accessory. The historical use of these test points is for indication of the presence of line voltage at the transformer or switchgear. Often, these testpoints do not provide the voltage ratio accuracy required for modern grid automation power quality and control applications.

### SUMMARY

Various embodiments of the present disclosure relate to sensors for high voltage, which may also serve as an insulating plug. This disclosure includes sensors that have an elongate plug body extending along an axis and impedance elements disposed on a substrate between a high voltage connection and a low voltage connection. The substrate extends around the axis. The sensors can provide a low voltage signal corresponding to a high voltage signal present in a separable connector.

In one aspect, the present disclosure relates to a sensor for a separable connector. The sensor may include an elongate plug body extending along an axis and comprising an insulating resin. The sensor may also include a high voltage connection at least partially encased by the insulating resin. The sensor may further include a low voltage connection spaced along the axis from the high voltage connection. Also, the sensor may include a substrate at least partially encased in the insulating resin and extending around the axis between a high voltage portion and a low voltage portion of the substrate. Further, the sensor may include a circuit disposed on the substrate and extending from the high voltage portion to the low voltage portion of the substrate. The circuit may include a plurality of first impedance elements electrically coupled between the high and low voltage connections. Still further, the sensor may include one or more second impedance elements electrically coupled to the circuit via the low voltage connection to form a voltage divider.

In another aspect, the present disclosure relates to a method. The method may include populating a flexible substrate with a plurality of first impedance elements in a plane to form a circuit between a high voltage portion and a low voltage portion of the substrate. The method may also include forming the substrate into a three-dimensional shape to space the high and low voltage portions along an axis. The method may further include molding an insulating resin to at least partially encase the circuit and the substrate to form a plug body.

It is to be understood that both the foregoing general description and the following detailed description present embodiments of the subject matter of the present disclosure, and are intended to provide an overview or framework for understanding the nature and character of the subject matter of the present disclosure as it is claimed.

### BRIEF DESCRIPTION OF THE DRAWINGS

FIG. 1A shows a system including the sensor, a separable connector, and an insulating cap.

FIG. 1B shows the sensor of FIG. 1A as a block diagram.

FIG. 2 shows a sensor including a substrate extending around an axis according to a first embodiment.

FIG. 3 shows the substrate of FIG. 2 before final assembly of the sensor.

FIG. 4 shows a sensor including a substrate and first impedance elements extending around an axis according to a second embodiment.

FIG. 5 shows the substrate of FIG. 4 before final assembly of the sensor.

FIG. 6A and FIG. 6B show a sensor having a substrate according to a third embodiment.

FIG. 7 shows the substrate of FIG. 6A and FIG. 6B before final assembly of the sensor.

FIG. 8 shows the substrate of FIG. 7 with a different circuit.

FIG. 9 shows a sensor having a substrate according to a fourth embodiment.

FIG. 10 shows the substrate of FIG. 9 before final assembly of the sensor.

FIG. 11 shows a sensor having a substrate according to a fifth embodiment.

FIG. 12 shows the substrate of FIG. 11 before final assembly of the sensor.

FIG. 13 shows a sensor having a substrate according to a sixth embodiment.

FIG. 14 shows the substrate of FIG. 13.

FIG. 15 shows a honeycomb-shaped substrate in a 2D shape.

FIG. 16 shows a spiral galaxy-shaped substrate a 2D shape.

FIGS. 17A-D together show a method of forming a sensor.

FIG. 18 shows a diagram of an electrical field emanating from a high voltage connection of a sensor.

The disclosure may be more completely understood in consideration of the following detailed description of various embodiments of the disclosure and the accompanying drawings.

### DETAILED DESCRIPTION

The present disclosure relates to sensors for high voltage separable connectors each having an elongate plug body extending along an axis and impedance elements disposed on a substrate, which extends around the axis, between a high voltage connection and a low voltage connection. Although reference is made herein to high voltage separable connectors, the sensor may be used with any voltage connector. Various other applications will become apparent to one of skill in the art having the benefit of the present disclosure.

Advantageously, the present disclosure provides a convenient and easy-to-use voltage sensor for a high voltage separable connector. The sensor may serve as an insulating plug that is free of exposed high voltage surfaces when inserted into the separable connector. The impedance elements between high and low voltage components may be spatially distributed in a variety of configurations in the plug. The distribution of impedance elements may reduce the electrical field stress on each impedance element and may utilize cost-effective, commercially-available components to form a voltage divider that may be suitable for use in high voltage sensing. The customizable nature of the sensor may be especially suitable for smart grid applications or other applications in which sensing requirements can vary widely from system to system and can change over time as smart grid technology develops.

The present disclosure relates to a sensor for a separable connector, which may also be used as an insulating plug. The sensor may include an elongate plug body extending along an axis. The plug body may include an insulating resin. A high voltage connection may be used to electrically couple the sensor to the separable connector. The high voltage connection may be at least partially encased by the insulating resin. A low voltage connection may be spaced along the axis from the high voltage connection. The low voltage connection may be used to electrically couple the sensor to other equipment, such as monitoring equipment. A substrate may extend around the axis between a high voltage portion and a low voltage portion of the substrate. The substrate may be at least partially encased by the insulating resin. A circuit may be disposed on the substrate extending from the high voltage portion to the low voltage portion of the substrate. The circuit may include a plurality of first impedance elements electrically coupled between the high and low voltage connections. One or more second impedance elements may be electrically coupled to the circuit via the low voltage connection to form a voltage divider. The substrate may include a flexible substrate, which may be populated in a two-dimensional (2D) plane and then moved into a three-dimensional (3D) shape before being at least partially encapsulated by the insulating resin. Alternatively, or additionally, the substrate may include a rigid substrate, which may be formed into a 3D shape, for example, by 3D printing techniques or other suitable techniques.

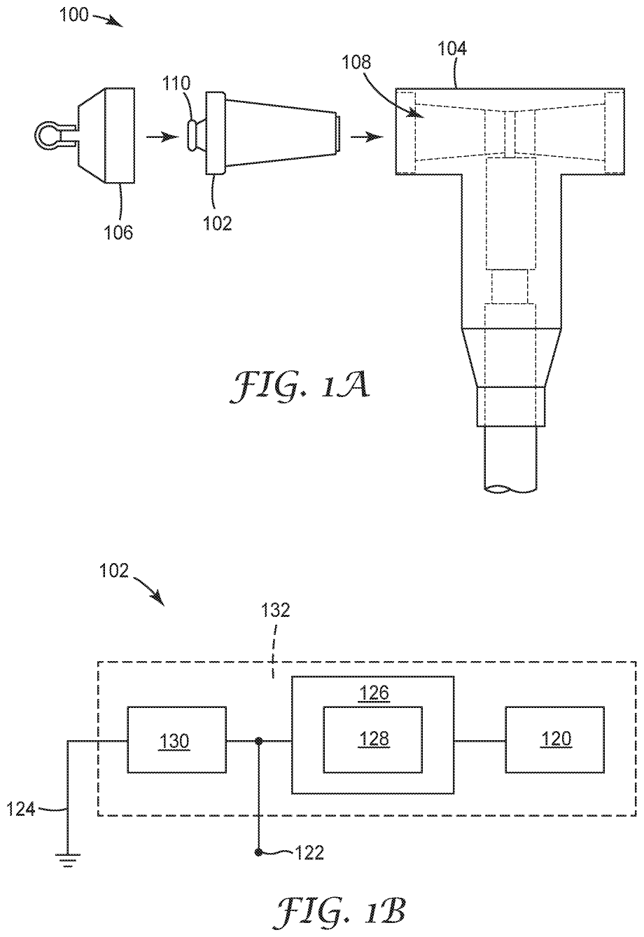

FIG. 1A shows a system 100 including a sensor 102, a separable connector 104, and an insulating cap 106. The system 100 and components thereof may be sized and shaped to meet, or otherwise be compatible with, an applicable standard, jurisdictional requirement, or end-user requirement for separable insulated connector systems. For example, the system 100 may be designed to meet the IEEE Standard 386 (2016) for an insulating plug for a separable connector. Specifically, the sensor 102 may be designed to be used as a 600A insulating plug. As another example, the system 100 may be designed to meet a similar International Electrotechnical Commission (IEC) standard, popular in Europe, which may employ a different size and shape for compatibility.

As illustrated, the sensor 102 may be in the shape of an insulating plug. The sensor 102 may be inserted into a receptacle 108 of the separable connector 104 and encase, or otherwise cover, a high voltage conductor, or high voltage conductive surface, disposed within the cavity. The separable connector 104 may include one, two, or more receptacles 108 (for example, in a T-Body).

The sensor 102 may be inserted in the same manner as a conventional insulating plug. In some embodiments, the sensor 102 may include a shoulder and a taper and the receptacle 108 may have complimentary features. The high voltage connector of the separable connector 104 may be a threaded rod, and the sensor 102 may include a high voltage connection with a complementary thread. The sensor 102 may be screwed onto the threaded high voltage conductor to secure the sensor 102 to the separable connector 104.

After being inserted and optionally secured, the sensor 102 may cover all, or at least some, high voltage surfaces in the receptacle 108 that would be otherwise exposed. An extending portion 110 of the sensor 102 may extend out of the receptacle 108 of the separable connector 104. The extending portion 110 may include a torque feature, such as a hex-shaped protrusion. The insulating cap 106 may be disposed over the sensor 102 to cover the extending portion 110. The insulating cap 106 may be frictionally secured to the separable connector 104. The insulating cap 106 may slide over at least a portion of the separable connector 104 and may be pulled off to expose the sensor 102. In some embodiments, extending portion 110 of the sensor 102 may have an outer surface that is formed of insulating material, and the insulating cap 106 may not be needed.

The sensor 102 may be a voltage sensor. The sensor 102 may provide a low voltage signal that corresponds to a high voltage signal present in the separable connector 104. The low voltage signal may be described as a voltage channel. The sensor 102 may include one or more impedance elements, such as resistors, capacitors, or inductors. In some embodiments, the impedance elements include one or more first impedance elements and one or more second impedance elements. The first and second impedance elements may be arranged as a voltage divider to provide the low voltage signal therebetween. The low voltage signal may correspond to the divided voltage signal.

The sensor 102 may provide an accuracy of the low voltage signal representing the high voltage signal that enables use in various smart grid applications for diagnosing degradation or other problems in the connected transformer, switchgear, or the larger connected grid, such as dips, sags, swells and other events. A higher accuracy sensor may facilitate the detection of smaller events or may facilitate more precise diagnosis of events. For example, for VOLT VAR control, a certain accuracy (for example, 0.7%) may be required to detect changes in the system, such as when on-load tap changers in transformers are changed. The accuracy may be defined as being less than or equal to an error value. Non-limiting examples of a maximum error value be up to about 1%, about 0.7%, about 0.5%, about 0.3%, about 0.2%, or even up to about 0.1%.

The temperature range over which the sensor 102 is accurate may be described as an operating temperature range. In the operating temperature range, the accuracy may be less than or equal to the error value for all temperatures within the range. The operating temperature range may be designed to meet a standard, jurisdictional requirement, or end-user requirement. Non-limiting examples of the operating temperature range include a lower end of no less than about −40° C., about −30° C., about −20° C., or even no less than about −5° C. Non-limiting examples of the operating temperature range include a higher end of no more than about 105° C., about 85° C., about 65° C., or even at most about 40° C. Non-limiting examples of the operating temperature range include being between about −5° C. to about 40° C., about −20° C. to about 65° C., about −30° C. to about 85° C., about −40° C. to about 65° C., or about −40° C. to about 105° C.

The sensor 102 may have a voltage rating, or be rated, to operate in high voltage systems, such as system 100. The sensor 102 may operate as a voltage sensor, an insulating plug, or both. The voltage rating may be designed to meet a standard, jurisdictional requirement, or end-user requirement. Non-limiting examples of the voltage rating of the sensor 102 in a three-phase system include about 2.5 kV, about 3 kV, about 5 kV, about 15 kV, about 25 kV, about 28 kV, about 35 kV, or about 69 kV (classified as phase-to-phase rms). In some embodiments, the voltage rating is no less than about 5 kV.

The frequency range over which the sensor 102 is accurate may be described as an operating frequency range. The frequency response may be flat or substantially flat, which may correspond to minimum variation, over the operating frequency range. Non-limiting examples of flatness may be plus or minus (+/−) about 3 dB, about 1 dB, about 0.5 dB, or even about 0.1 dB. The frequency response may be designed to meet a standard, jurisdictional requirement, or end-user requirement. The operating frequency range may extend to about the 50th harmonic, or even up to the 63rd harmonic, of a base frequency of the high voltage signal present in the separable connector 104. Non-limiting examples of the operating frequency range may include one or more of the base frequency of about 60 Hz (or about 50 Hz), the 50th harmonic of about 3 kHz (or about 2.5 kHz), the 63rd harmonic of about 3.8 kHz (or about 3.2 kHz), and higher. The frequency response may also remain stable over all or substantially all the operating temperature range. Certain remote terminal units (RTUs) or intelligent electronic devices (IEDs) may take advantage of one or more of these higher order harmonics.

FIG. 1B shows the sensor 102 as a block diagram. The sensor 102 may include a high voltage connection 120. The high voltage connection 120 may be used to electrically coupled the sensor 102 to a separable connector. The high voltage connection 120 may be electrically coupled to a circuit 128 disposed on a substrate 126. The substrate 126 may be a printed circuit board, which may be flexible or rigid. The circuit 128 may include a plurality of first impedance elements. A low voltage connection 122 may be electrically coupled to the circuit 128 and to one or more second impedance elements 130. A voltage divider may be formed having an output at the low voltage connection 122, which preferably represents a fraction of the voltage of the high voltage connection 120. A ground connection 124 may be electrically coupled to the one or more second impedance elements. One or more components of the sensor 102 may be at least partially encased (for example, partially or fully) by an insulating resin 132.

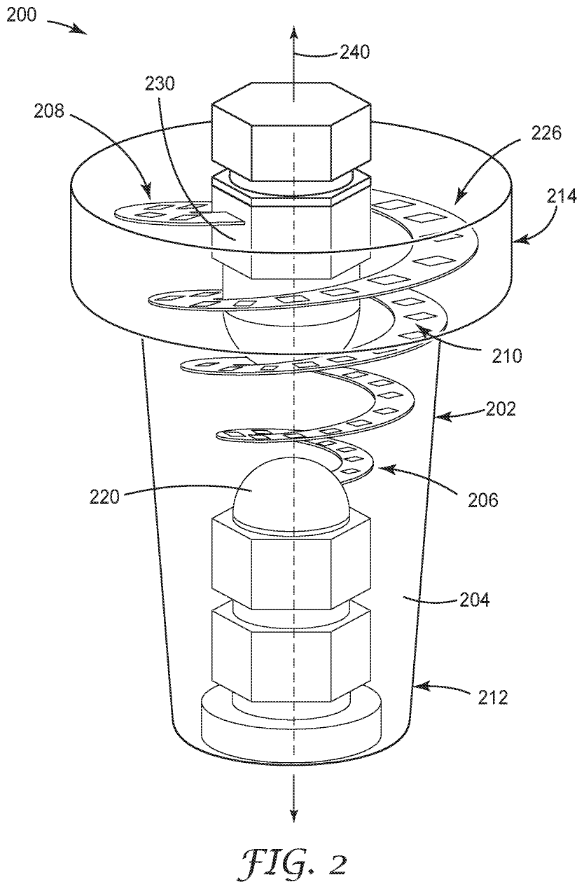

Many of the parts and components depicted in FIGS. 2-18 are the same or similar to those depicted in, and described with regard to, FIGS. 1A, 1B, as well as throughout FIGS. 2-18. Reference is made to the discussion above regarding FIGS. 1A, 1B, as well as other related description in FIGS. 2-18, for numbered elements depicted in, but not specifically discussed with regard to, any one of FIGS. 2-18.

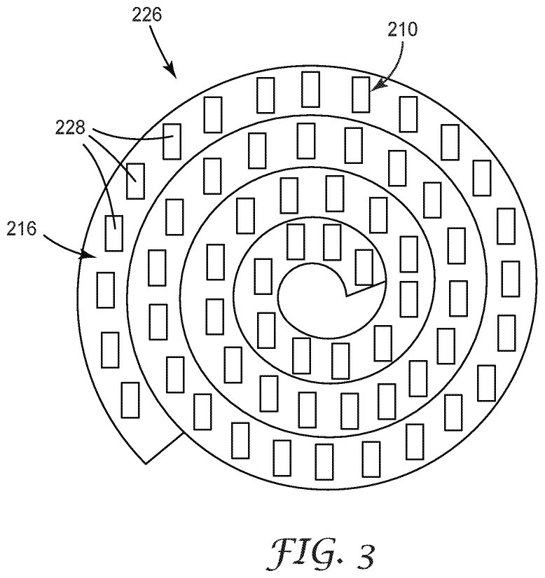

FIG. 2 shows a sensor 200 including a substrate 226 extending around an axis 240. FIG. 3 shows the substrate 226 before final assembly of the sensor 200.

The axis 240 may be described as a longitudinal axis. The sensor 200 may include a plug body 202. The plug body 202 may be elongate between a high voltage end portion 212 and a low voltage end portion 214. The elongate plug body 202 may extend along the axis 240.

The plug body 202 may include an insulating resin 204. The resin 204 may include any suitable electrically insulating, or dielectric, material or materials. The resin 204 may be formed by any suitable process, such as overmolding.

The insulating resin 204 may insulate components in the sensor 200, such as the substrate 226, from an external environment due to high voltage present in the sensor when in use. The insulating resin 204 may at least partially encase a high voltage connection 220. The insulating resin 204 may also at least partially encase a low voltage connection 230. Also, the insulating resin 204 may at least partially encase the substrate 226.

The low voltage connection 230 may be spaced along the axis 240 from the high voltage connection 220. The high voltage connection 220 may be operatively coupled to a high voltage connection of a separable connector. The high voltage connection 220 may be formed of any suitable material, such as aluminum or steel, and may have a coefficient of thermal expansion (CTE) matched to the high voltage connection of the separable connector. The low voltage connection 230 may provide a low voltage signal to other instruments. The low voltage signal may be conditioned before leaving the sensor 200.

The substrate 226 may extend around the axis 240 between a high voltage portion 206 and a low voltage portion 208 of the substrate 226. The low voltage portion 208 of the substrate 226 may be adjacent, or proximate, to the low voltage connection 230. The substrate 226 may be flexible or rigid. In some embodiments, the substrate 226 may extend a plurality of turns around the axis 240. The high voltage portion 206 and the low voltage portion 208 may be disposed on opposite ends of the substrate 226.

A circuit 210 may be disposed on the substrate 226. The circuit 210 may extend from the high voltage portion 206 to the low voltage portion 208 of the substrate 226. The circuit 210 may include a plurality of impedance elements, such as first impedance elements 228, electrically coupled between the high and low voltage connections 220, 230.

The substrate 226 and the circuit 210 disposed thereon may be arranged in various configurations relative to the axis 240 and to one another. For example, the circuit 210 may extend at least partially around the axis 240. The circuit 210 may extend a plurality of turns around the axis 240. The circuit 210 may extend in a helical path. The circuit 210 may extend around the low voltage connection 230. The circuit 210 may extend no more than one turn around the axis 240 for each turn of the substrate 226.

The substrate 226 may be flexible to allow the substrate to be moved between a planar shape (for example, linear) and a curved shape (for example, non-linear). The substrate 226 may be arranged in the planar shape before first impedance elements 228 are populated. The planar shape may allow a conventional pick and place machine to populate the first impedance elements 228 on the substrate 226 in the manufacturing process. The substrate 226 including the first impedance elements 228 disposed thereon may then be moved into a curved shape, as shown in FIG. 2, for final assembly of the sensor 200.

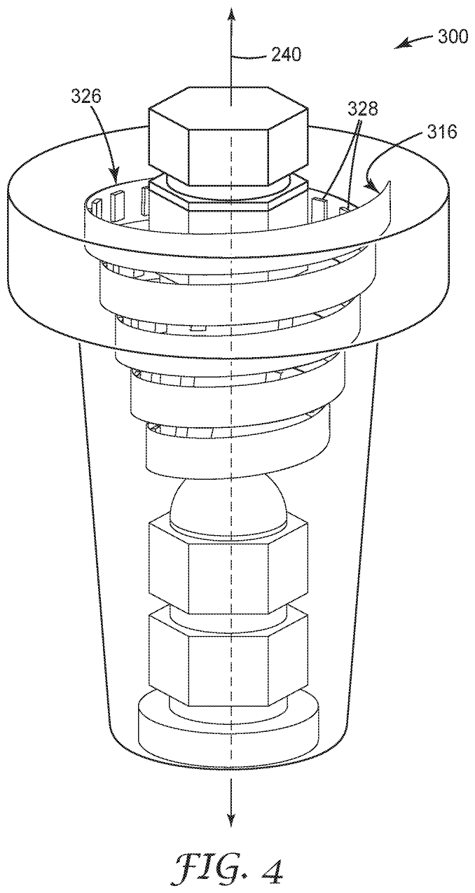

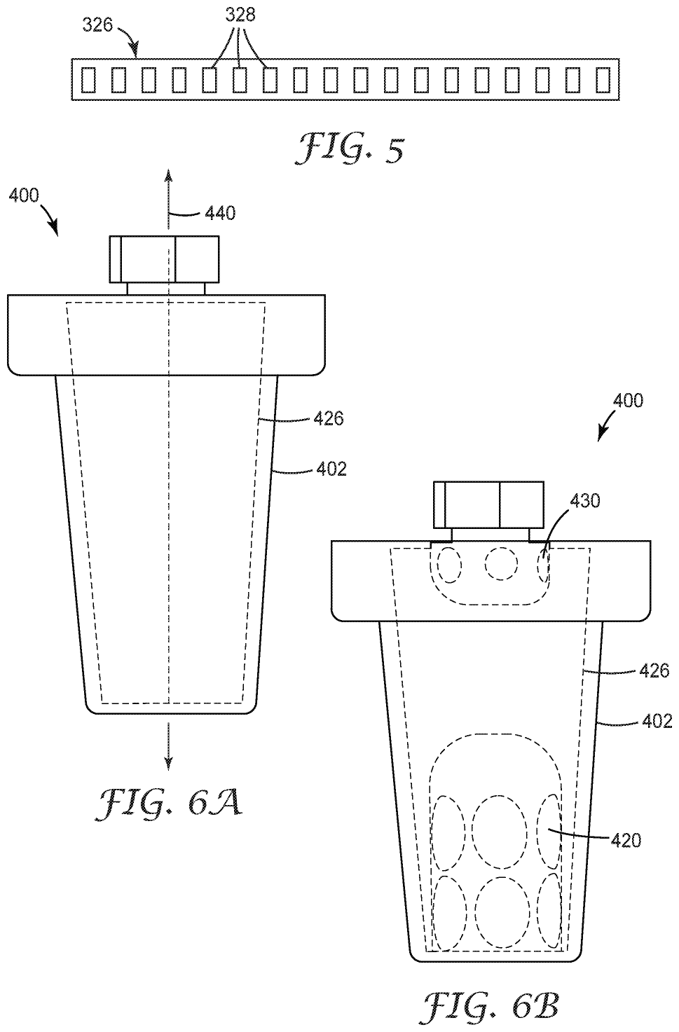

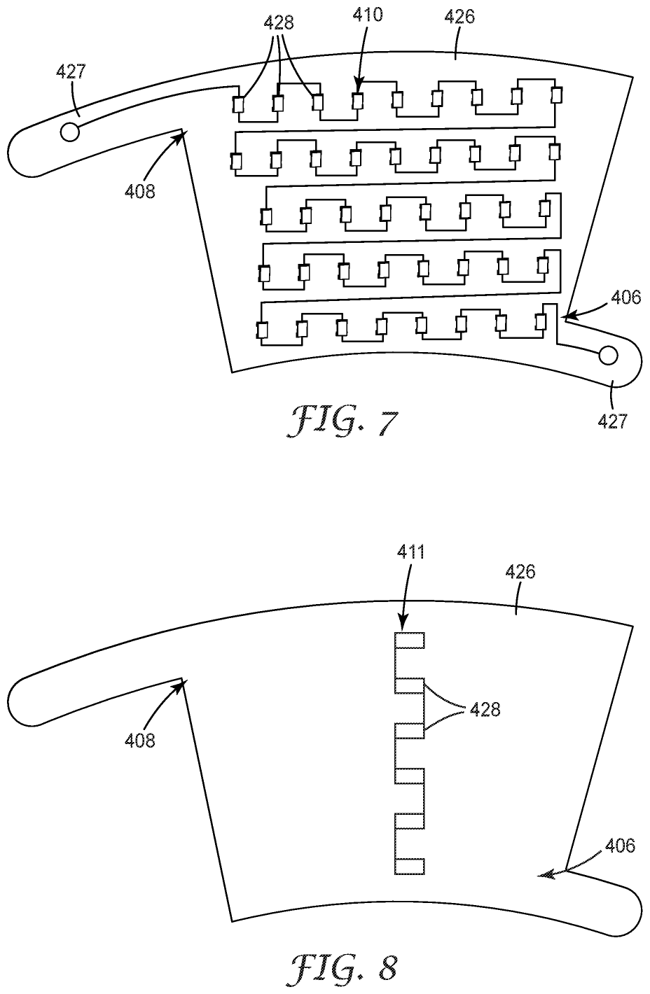

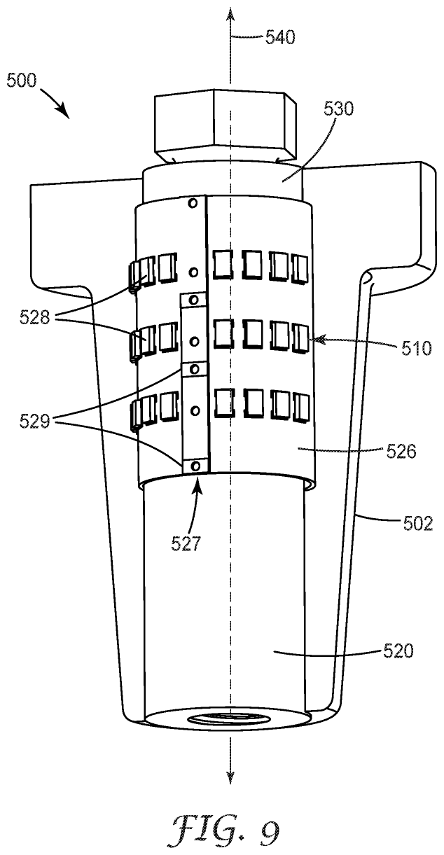

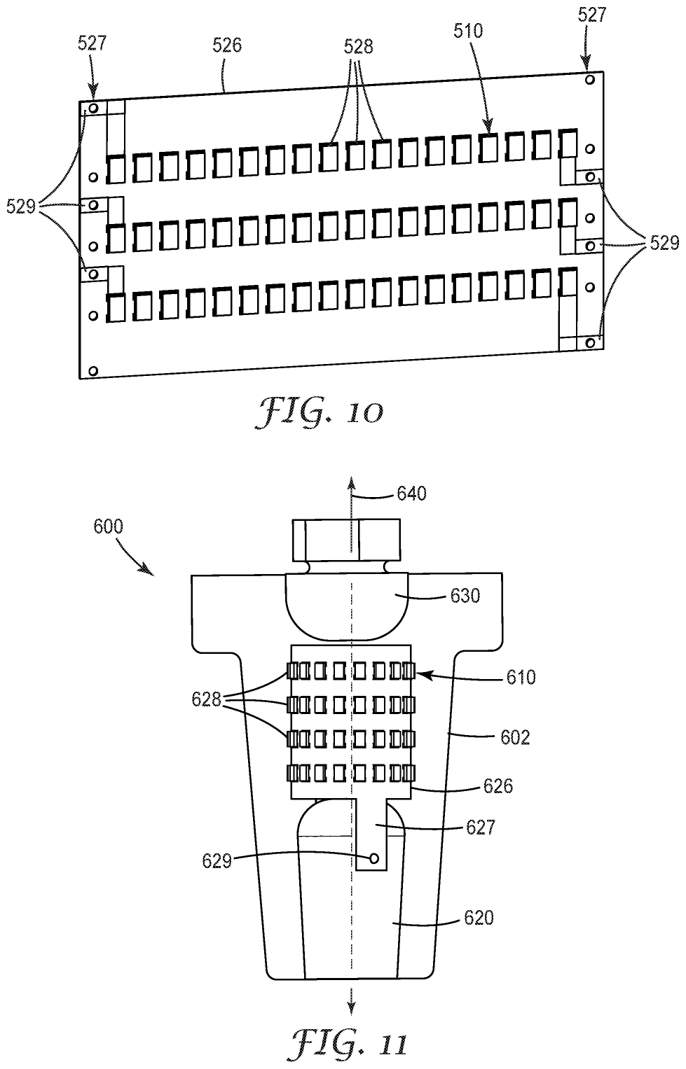

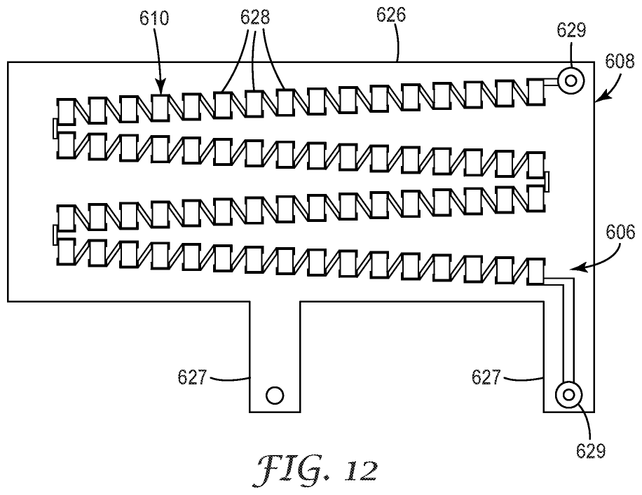

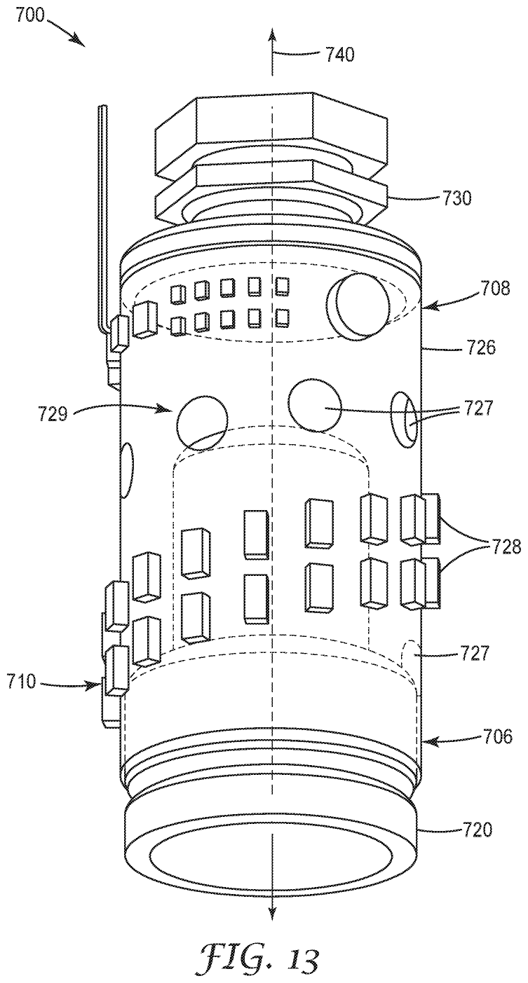

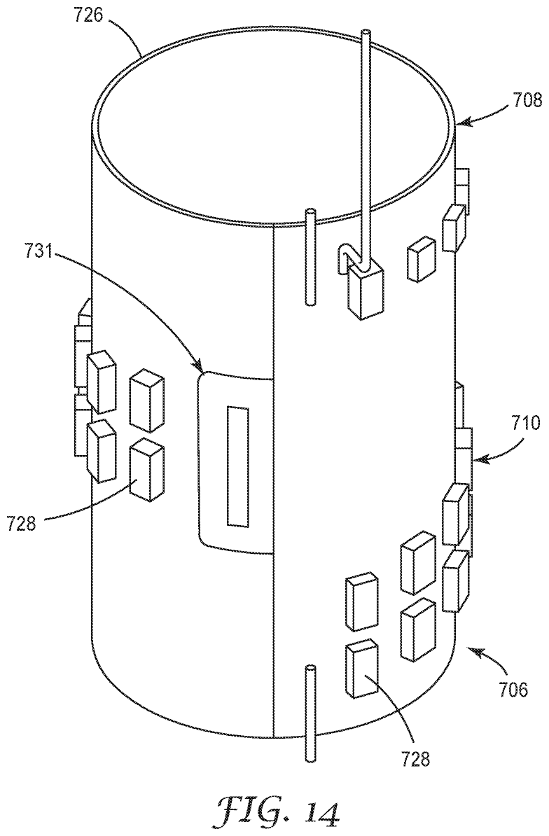

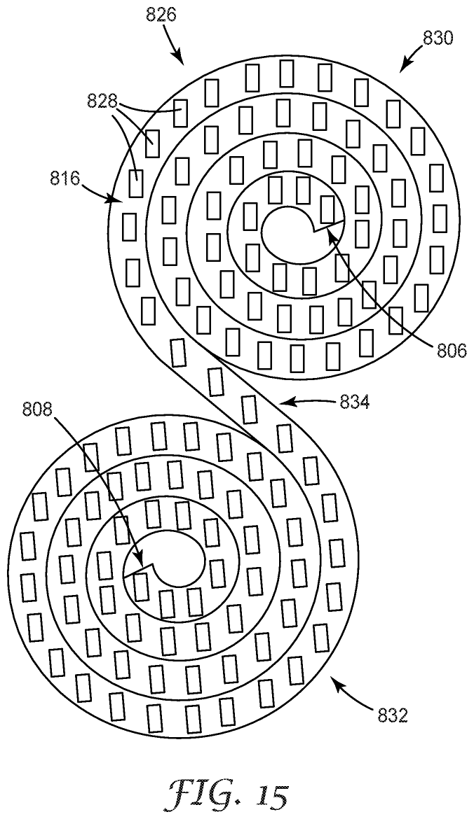

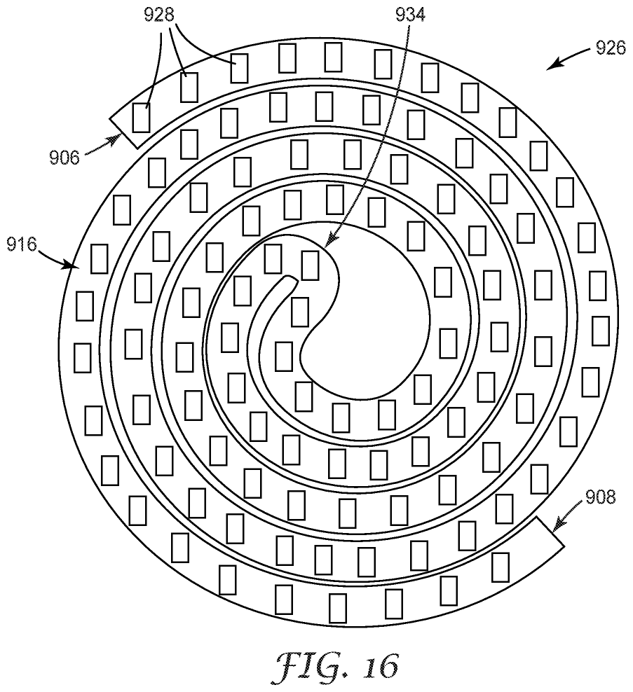

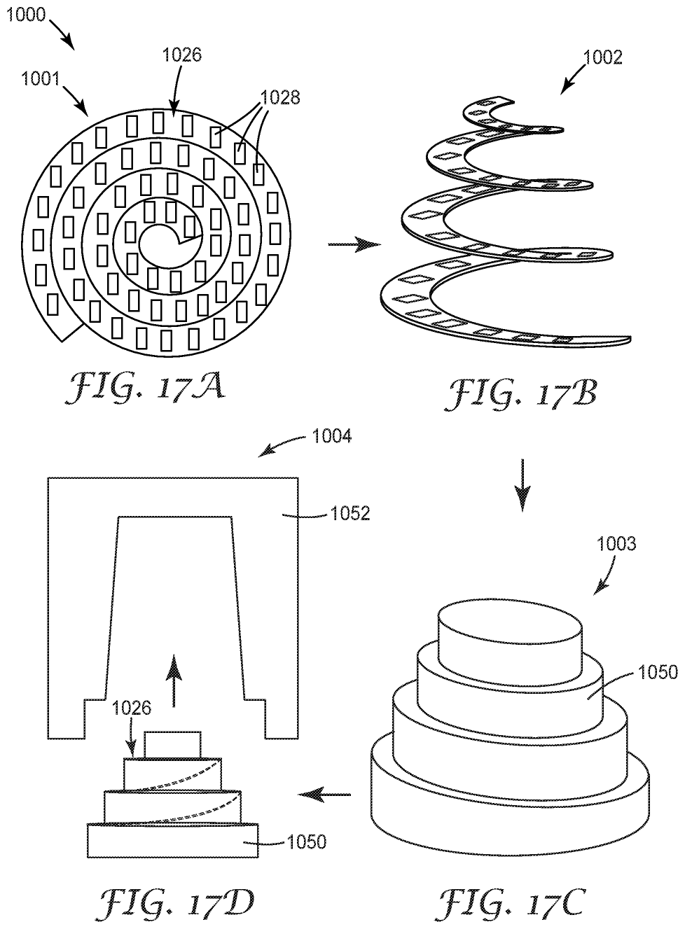

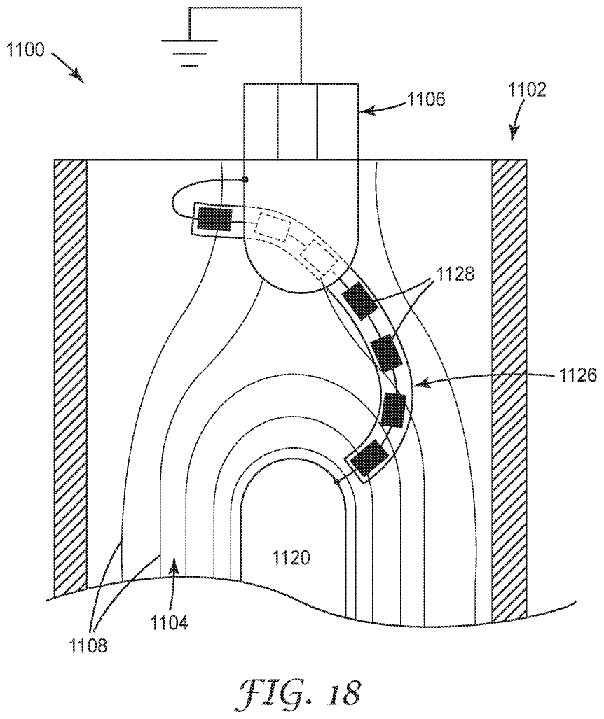

The first impedance elements 228 may be disposed between a high voltage portion and a low voltage portion of the substrate 226 and form part of the circuit 210. Although the electrical couplings or connections are not shown in each figure, some or all the impedance elements on the substrate, such as impedance elements 228, impedance elements 328 (FIGS. 4 and 5), impedance elements 428 (FIGS. 7 and 8), impedance elements 528 (FIGS. 9 and 10), impedance elements 628 (FIGS. 11 and 12), impedance elements 728 (FIGS. 13-14), impedance elements 828 (FIG. 15), impedance elements 928 (FIG. 16), impedance elements 1028 (FIG. 17A), and/or impedance elements 1128 (FIG. 18), may be electrically coupled to one another in a respective circuit. Some, or all, of the first impedance elements 228 may be electrically coupled in series. Some, or all, of the first impedance elements 228 may be electrically coupled in parallel. The first impedance elements 228 may be spatially arranged based on electrical field stress from the high voltage connection 220, a shape of the plug body 202, or both.

The first impedance elements 228 may be disposed on a surface 216 of the substrate 226. When assembled, the surface 216 may define a width of the substrate 226 that is substantially orthogonal to the axis 240.

FIG. 4 shows a sensor 300 including a substrate 326 and first impedance elements 328 extending around the axis 240. FIG. 5 shows the substrate 326 before final assembly of sensor 300.

The first impedance elements 328 may be disposed on a surface 316 of the substrate 326. The substrate 326 may extend along the same or a similar path to substrate 226 (FIG. 2). However, substrate 326 differs from substrate 226 in that the surface 316 may define a width of the substrate 326 that is substantially parallel to the axis 240 (instead of orthogonal).

The substrate 326 may be flexible to allow the substrate to be moved between a planar shape and a curved shape. The substrate 326 may be arranged in the planar shape before first impedance elements 328 are populated. The planar shape may allow a conventional pick and place machine to populate the first impedance elements 328 on the substrate 326 in the manufacturing process. The substrate 326 including the first impedance elements 328 disposed thereon may then be moved into a curved shape, as shown in FIG. 4, for final assembly of the sensor 300.

FIG. 6A and FIG. 6B show a sensor 400 having a substrate 426. FIG. 6A shows the sensor 400 with a plug body 402 cutaway. FIG. 6B shows the sensor 400 with both the plug body 402 and the substrate 426 cutaway and both a high voltage connection 420 and a low voltage connection 430 being visible. FIG. 7 shows the substrate 426 before final assembly of the sensor 400.

In some embodiments, the substrate 426 may extend less than two turns around the axis 440. For example, the substrate 426 may extend about one turn around an axis 440. The substrate 426 extends around both the high voltage connection 420 and the low voltage connection 430.

Substrate 426 may be flexible to allow the substrate to be moved between a planar shape and a curved shape. The substrate 426 may be arranged in the planar shape before first impedance elements 428 are populated. The substrate 426 including the first impedance elements 428 disposed thereon may then be moved into a curved shape, as shown in FIGS. 6A and 6B, for final assembly of sensor 400.

A circuit 410, disposed on the substrate 426 and including the first impedance elements 428, may extend in an undulating path between a high voltage portion 406 and a low voltage portion 408 of the substrate.

One or more overlapping tabs 427 may extend from the substrate 426. The overlapping tabs 427 may be integrally formed with the substrate 426. In the curved shape of the substrate 426, the overlapping tabs 427 may be used to couple one side of the substrate 426 to an opposite side. Each of the overlapping tabs 427 may be shorter than the width of the substrate 426, or as illustrated, the major portion of the substrate between the overlapping tabs. The substrate 426, including or not including the overlapping tabs 427, may extend less than two turns around the axis 440.

FIG. 8 shows the substrate 426 before final assembly with a different circuit 411 disposed on the substrate including first impedance elements 428. The circuit 411 may extend substantially parallel to the axis 440 (FIG. 6A) between the low voltage portion 406 and the high voltage portion 408 of the substrate 426, instead of in an undulating path therebetween like circuit 410 (FIG. 7). The circuit 411 may be arranged in a linear manner. For example, the first impedance elements 428 may be arranged to align to an axis.

FIG. 9 shows a sensor 500 having a substrate 526 and a cutaway plug body 502. FIG. 10 shows the substrate 526 before final assembly.

The substrate 526 may extend less than two turns around the axis 540. In particular, the substrate 526 may include overlapping regions 527. One or more conductors 529 may be disposed in the overlapping regions 527.

A circuit 510 may be disposed on the substrate 526 and may include first impedance elements 528, as well as the conductors 529. The circuit 510 may be electrically coupled between a high voltage connection 520 and a low voltage connection 530. The circuit 510 may extend more than one turn around axis 540. In particular, the circuit 510 may extend more than one turn for each turn of the substrate 526. The circuit 510 may extend in a helical path. The helical path may extend around the axis 540.

Substrate 526 may be flexible to allow the substrate to be moved between a planar shape and a curved shape. The substrate 526 may be arranged in the planar shape before first impedance elements 528 are populated. The substrate 526 including the first impedance elements 528 disposed thereon may then be moved into a curved shape, as shown in FIG. 9, for final assembly of sensor 500.

First and second overlapping regions 527 may be disposed on opposite sides of the substrate 526. The overlapping regions 527 may be integrally formed with the substrate 526. In the curved shape of the substrate 526, the overlapping regions 527 may be used to couple one side of the substrate to an opposite side. Each of the overlapping regions 527 may include vias to facilitate securing the overlapping regions together and conductors 529 to electrically couple the first impedance elements 528 together.

The circuit 510 may be arranged into a plurality of rows, each including a plurality of first impedance elements 528. The rows may be electrically isolated from one another in the planar shape of the substrate. Each row may be terminated in one of the overlapping regions 527. In particular, both ends of each row may be terminated in different overlapping regions 527. The conductors 529, which may include conductive vias, may be used to electrically couple the rows of the circuit 510 together in the curved shape of the substrate 526. The conductors 529 may also be used to connect the circuit 510 to the high voltage and low voltage connections 520, 530.

FIG. 11 shows a sensor 600 having a substrate 626 and a cutaway plug body 602. FIG. 12 shows the substrate 626 before final assembly.

The substrate 626 may extend less than two turns around an axis 640. The substrate 626 may include one or more connecting tabs 627 extending axially from the substrate 626. One or more conductors 629 may be disposed on the connecting tabs 627.

A circuit 610 may be disposed on the substrate 626 and may include first impedance elements 628, as well as the conductors 629. The circuit 610 may be electrically coupled between a high voltage connection 620 and a low voltage connection 630.

Substrate 626 may be flexible to allow the substrate to be moved between a planar shape and a curved shape. The substrate 626 may be arranged in the planar shape before the first impedance elements 628 are populated. The substrate 626 including the first impedance elements 628 disposed thereon may be moved into a curved shape, as shown in FIG. 11, for final assembly of sensor 600.

The circuit 610 may extend in an undulating path between a high voltage portion 606 and a low voltage portion 608 of the substrate 626.

Connecting tabs 627 may be disposed on the same side of the substrate 626. In some embodiments (not shown), the connecting tabs 627 may be disposed on opposite sides of the substrate 626. The connecting tabs 627 may be integrally formed with the substrate 626. In the curved shape of the substrate 626, the conductors 629 disposed on the connecting tabs 627 may be used to couple the substrate 626 to the high voltage connection 620, the low voltage connection 630, or both. In the curved shape of the substrate 626, the connecting tabs 627 may connect to opposite sides of the same high or low voltage connection 620, 630.

FIG. 13 shows a sensor 700 having a substrate 726 and a plug body (hidden from view). FIG. 14 shows the substrate 726 without the high and low voltage connections 720, 730.

The substrate 726 may extend less than two turns around an axis 740. First impedance elements 728 may be disposed on a surface 729 of the substrate 726. The substrate 726 may couple to a high voltage connection 720 and a low voltage connection 730 to at least partially enclose an interior volume therebetween. The substrate 726 may include one or more apertures 727 extending through the surface 729 of the substrate. The apertures 727 may allow an insulating resin of the plug body to flow therethrough to fill in air bubbles in the interior volume during the manufacturing process (for example, an overmolding process). Air bubbles may be undesirable in various high voltage applications.

A circuit 710 may be disposed on the substrate 726. The circuit 710 may be electrically coupled between the high and low voltage connections 720, 730. The circuit 710 may extend from a high voltage portion 706 to a low voltage portion 708 of the substrate. The circuit 710 may extend more than one turn around the axis 740 for each turn of the substrate 726.

One or more coupling tabs 731 may extend from the substrate 726. The coupling tabs 731 may be integrally formed with the substrate 726. The substrate 726 may be flexible or at least semi-rigid to allow the substrate to move into a curved shape. In the curved shape of the substrate 726, the coupling tabs 731 may be used to couple one side of the substrate to an opposite side. The coupling tabs 731 may overlap with a portion of another tab or a portion of the substrate 726 to facilitate securing the sides of the substrate together. Each of the coupling tabs 731 may include conductors (not shown) to facilitate to electrically coupling the first impedance elements 728 together to form the circuit 710.

FIG. 15 shows a substrate 826 having multiple turns in a double spiral shape. A plurality of impedance elements 828 may be disposed on the surface 816. As illustrated, the substrate 826 in a 2D shape that may be used before disposal into a plug body, such as during population of the substrate with first impedance elements 828. The substrate 826 may be described as two spirals 830, 832 connected to one another adjacent or proximate to a mid-portion 834. A high voltage portion 806 and a low voltage portion 808 may be disposed in the center of each spiral 830, 832, respectively.

The 2D shape may be moved into the 3D shape by placing the substrate 826 on a structure or otherwise suspend the substrate to form the desired shape. When disposed in a plug body, the substrate 826 may be in a 3D shape (not shown).

In the 3D shape, the substrate 826 may be tapered. In some embodiments, the substrate 826 may taper toward the high voltage portion 806 of the substrate or a high voltage connection (not shown), the low voltage portion 808 of the substrate or the low voltage connection (not shown), or both. In some embodiments, the substrate 826 may form a cone shape, or double cone shape, which tapers toward both the high voltage portion 806 and the low voltage portion 808. The shape may also be described as a honeycomb shape.

After moving into the 3D shape, the substrate 826 may have a half-twist. The half-twist may be proximate to the mid-portion 834 between the high voltage portion 806 and the low voltage portion 808. The half-twist may be disposed within one turn of the substrate 826. The half-twist may be spread out over more than one turn of the substrate 826.

FIG. 16 shows a substrate 926 having multiple turns in an interlaced spiral shape. As illustrated, the substrate 926 in a 2D shape may be used before disposal into a plug body, such as during population of the substrate with first impedance elements 928 disposed on a surface 916. The substrate 926 may be described as two interlaced spirals. The spirals may rotate in the same direction (for example, clockwise or counter-clockwise) from a mid-portion 934. The spirals may be connected with one another such that the center of each spiral meets adjacent or proximate to the mid-portion 934 of the substrate 926.

The 2D shape may be moved into the 3D shape by placing the substrate 926 on a structure or otherwise suspend the substrate to form the desired shape. The 3D shape may be described as a flared shape. In some embodiments, the substrate 926 flares toward the high voltage portion 906 of the substrate or a high voltage connection (not shown), the low voltage portion 908 of the substrate or a low voltage connection (not shown), or both. In some embodiments, the substrate 926 may have a spiral galaxy shape, which flares toward both the high voltage portion 906 and the low voltage portion 808 (for example, like two opposing cones with apices pointed at one another).

FIGS. 17A, 17B, 17C, and 17D show processes 1001, 1002, 1003, 1004, respectively, in an illustrative method 1000 of forming a sensor.

FIG. 17A shows a substrate 1026 in a 2D shape populated with first impedance elements 1028. The substrate 1026 may be flexible. The substrate 1026 may be populated with a plurality of first impedance elements 1028 while the substrate is in a planar 2D shape. The substrate 1026 may then be cut, for example, to form a plurality of turns. Any suitable cutting technique may be used, such as die cutting, laser cutting, water jet cutting, mechanical profile cutting, and profile milling. In one or more embodiments, the substrate 1026 may be pre-cut before populating the first impedance elements 1028.

FIG. 17B shows the substrate 1026 moved into a 3D shape. The 3D shape may space high and low voltage portions of the substrate 1026 from one another along a longitudinal axis.

FIG. 17C shows a shaping structure 1050 to support the substrate 1026 in the 3D shape for molding. The substrate 1026 may be fitted to the shaping structure 1050 to move the substrate 1026 into a 3D shape. The shaping structure 1050 may support at least high and low voltage portions of the substrate 1026. The shaping structure 1050 may also support the substrate 1026 between the high and low voltage portions. In some embodiments, the shaping structure 1050 is at least partially electrically conductive. The shaping structure 1050 may electrically couple to a circuit of the substrate 1026.

FIG. 17D shows the shaping structure 1050 with substrate 1026 coupled thereto being placed into a mold 1052 for forming a plug body around the substrate 1026 and shaping structure 1050. In particular, an insulating resin may be molded to at least partially encase the circuit of the substrate to form the plug body. In some embodiments, the shaping structure 1050 may be included as part of the plug body. In some embodiments, the shaping structure 1050 may be removed from the insulating resin after molding.

The shaping structure 1050, or other structures having the same shape, may be used with different interface-specific molds. For example, plug bodies having different shapes may be formed using the same shaping structure 1050, or another shaping structure 1050 having the same shape, to simplify the manufacturing process while accommodating a variety of separable connector shapes.

FIG. 18 shows a system 1100 including a sensor 1102 and an electrical field 1104 emanating from a high voltage connection 1120, which may place an electrical field stress on various components of the sensor. As illustrated, the electric field 1104 may be characterized by a plurality of isopotential lines 1108. The position and shape of the isopotential lines 1108 of the electric field 1104 may depend on the conductivity path to ground using the low voltage connection 1106 from the high voltage connection 1120. The spatial arrangement of first impedance elements 1128 on the substrate 1126 may be based on, for example, the electrical field stress from the high voltage connection 1120, the shape of the plug body of the sensor 1102, or both. In some embodiments, the voltage drop across each of the first impedance elements 1128 may be substantially equal when subjected to electrical field stress from the high voltage connection 1120.

In some embodiments, the first impedance elements 1128 may have the same impedance values (for example, nominal impedance values). In some embodiments, the first impedance elements 1128 may have different impedance values. The impedance values may be selected based on electrical field stress from the high voltage connection 1120.

Thus, various embodiments of the SENSORS WITH IMPEDANCE ELEMENTS ON SUBSTRATE FOR HIGH VOLTAGE SEPARABLE CONNECTORS are disclosed. Although reference is made herein to the accompanying set of drawings that form part of this disclosure, one of at least ordinary skill in the art will appreciate that various adaptations and modifications of the embodiments described herein are within, or do not depart from, the scope and spirit of this disclosure. For example, aspects of the embodiments described herein may be combined in a variety of ways with each other. Therefore, it is to be understood that, within the scope of the appended claims, the claimed invention may be practiced other than as explicitly described herein.

All scientific and technical terms used herein have meanings commonly used in the art unless otherwise specified. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (for example 1 to 5 includes 1, 1.5, 2, 2.75, 3, 3.80, 4, and 5) and any range within that range. Herein, the terms “up to” or “no greater than” a number (for example, up to 50) includes the number (for example, 50), and the term “no less than” a number (for example, no less than 5) includes the number (for example, 5).

The terms “coupled” or “connected” refer to elements being attached to each other either directly (in direct contact with each other) or indirectly (having one or more elements between and attaching the two elements).

Terms related to orientation, such as “side,” “end,” and “longitudinal,” are used to describe relative positions of components and are not meant to limit the orientation of the embodiments contemplated. For example, an embodiment described as having a “top” and “bottom” also encompasses embodiments thereof rotated in various directions unless the content clearly dictates otherwise.

Reference to “one embodiment,” “an embodiment,” “certain embodiments,” or “some embodiments,” etc., means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiments.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

As used herein, “have,” “having,” “include,” “including,” “comprise,” “comprising” or the like are used in their open-ended sense, and generally mean “including, but not limited to.” It will be understood that “consisting essentially of,” “consisting of,” and the like are subsumed in “comprising,” and the like.

The phrases “at least one of,” “comprises at least one of,” and “one or more of” followed by a list refers to any one of the items in the list and any combination of two or more items in the list.

1. A sensor for a separable connector comprising:
an elongate plug body extending along an axis and comprising an insulating resin;
a high voltage connection at least partially encased by the insulating resin;
a low voltage connection spaced along the axis from the high voltage connection;
a substrate at least partially encased in the insulating resin and extending around the axis between a high voltage portion and a low voltage portion of the substrate;
a circuit disposed on the substrate and extending from the high voltage portion to the low voltage portion of the substrate, the circuit comprising a plurality of first impedance elements electrically coupled between the high and low voltage connections; and
one or more second impedance elements electrically coupled to the circuit via the low voltage connection to form a voltage divider.

2. The sensor according to claim 1, wherein the circuit extends at least partially around the axis.

3. The sensor according to claim 1, wherein the circuit extends a plurality of turns around the axis.

4. The sensor according to claim 1, wherein the circuit extends in a helical path.

5. The sensor according to claim 1, wherein the circuit extends in an undulating path between the high and low voltage portions of the substrate.

6. The sensor according to claim 1, wherein the low voltage portion of the substrate is proximate to the low voltage connection.

7. The sensor according to claim 1, wherein the circuit extends around the low voltage connection.

8. The sensor according to claim 1, wherein the circuit extends substantially parallel to the axis.

9. The sensor according to claim 1, wherein the substrate extends a plurality of turns around the axis.

10-15. (canceled)

16. The sensor according to claim 1, wherein the first impedance elements are spatially arranged based on electrical field stress from the high voltage connection, a shape of the plug body, or both.

17. The sensor according to claim 1, wherein a voltage drop across each of the first impedance elements is substantially equal when subjected to electrical field stress from the high voltage connection.

18-22. (canceled)

23. The sensor according to claim 1, wherein the substrate has a shape that tapers toward the high voltage portion, the low voltage portion, or both.

24. The sensor according to claim 23, wherein the substrate forms a cone shape.

25-28. (canceled)

29. A method comprising:
populating a flexible substrate with a plurality of first impedance elements in a plane to form a circuit between a high voltage portion and a low voltage portion of the substrate;
forming the substrate into a three-dimensional shape to space the high and low voltage portions along an axis; and
molding an insulating resin to at least partially encase the circuit and the substrate to form a plug body.

30-39. (canceled)
